(19) United States
(12) Patent Application Publication
(10) Pub. No.: US 2004/0227199 A1
(43) Pub. Date: Nov. 18, 2004

(54) Minute flow passage and micro-chemical chip including the same

(75) Inventors: Satoshi Fukuyama, Numazu-Shi (JP); Hiroshi Murakoshi, Shizuoka-Ken (JP); Hajime Sudo, Chiba-Ken (JP); Hiroyuki Goto, Ebina-Shi (JP)

Correspondence Address: PILLSBURY WINTHROP, LLP, P.O. BOX 10500, MCLEAN, VA, 22102, US

(73) Assignees: TOSHIBA KIKAI KABUSHIKI KAISHA, Tokyo-To (JP); KABUSHIKI KAISHA TOSHIBA, Tokyo (JP); TOSHIBA CERAMICS CO., LTD., Tokyo-To (JP)

(21) Appl. No.: 10/438,271

(22) Filed: May 15, 2003

(51) Int. Cl. H01L 27/14

(52) U.S. Cl. 257/414

(57) ABSTRACT

A minute circuit is configured by protruded flow passage walls provided on the surfaces, opposite to each other, of first and second flat members disposed facing each other. This configuration includes a case where the minute circuit has the first flat member including a pair of wall members spaced a width of said minute flow passage from each other and provided in a protruded shape on one surface, and the second flat member fitted so as to abut on at least an apex portion of the wall member, and a case where the minute circuit has the first flat member including a first wall member structuring one side wall of the minute flow passage and formed in a protruded shape, and the second flat member including a second wall member structuring the other side wall of the minute flow passage and formed in a protruded shape, and the surface of the first flat member and the second flat member are disposed facing each other so that a width of the minute flow passage is defined by the first wall member and the second wall member.

### BACKGROUND OF THE INVENTION

The present invention is related to a minute flow passage, a micro-chemical chip and methods thereof.

A micro-chemical chip includes a glass substrate with its one side that is several tens of millimeters (mm), on which optical analysis oriented minute grooves that are each on the order of 100 μm in width and 50 μm in depth and flow passages each including a cavity that is several hundreds of micro millimeters (μm) in diameter are integrated. This micro-chemical chip is utilized for effecting reaction, synthesis and extraction of a minute quantity of chemical substance in a flowing state, and for separating DNA fragments cut off to a variety of lengths. The micro-chemical chip utilized for a DNA analysis is known as a DNA chip.

The analysis using this micro-chemical chip aims at analyzing a fluid flowing through the aforementioned groove provided on the glass substrate by an electrophoresis, etc. or a chemical substance accumulated in the cavity, and is executed in such a way that the minute groove or cavity is irradiated with infrared-rays, and reflected light therefrom and transmitted light therethrough are led to an analyzing portion via an optical element.

The minute flow passage utilized for these applications is a minute tube in which a representative dimension of an opening in section is several tens through several hundreds of micro millimeters (μm).

FIG. 1 shows one example of the micro-chemical chip serving as a minute straight tubelike flow passage (capillary) electrophoretic device utilized for separating the DNA fragments and so on. Further, FIG. 2 is a sectional view of a minute flow passage 2. FIG. 3 is a perspective view of the micro-chemical chip.

A quantitative flow passage 2 and a detection flow passage 3 as two streaks of minute flow passages extending straight and intersecting in cross, are grooved on a transparent insulating substrate 1. These minute flow passages 2, 3 are sealed by superposing a sealing transparent insulating plate 4 thereon and fixedly bonding them with an adhesive, etc. This sealing transparent insulating plate 4 is formed with an opening 5 for injecting and extracting a sample, corresponding to the minute flow passage. Further, the sealing transparent insulating plate 4 is provided with electrodes at both ends of each minute flow passage. Moreover, a gel having a meshed structure of a nanometer scale is filled and sealed in an interior of the minute flow passage.

Herein, the optical analysis is, as will be described later on, conducted in the flow passage, and hence quartz excellent of a optical characteristic is often employed for the transparent insulating substrate. Then, the flow passage is normally configured in a way that digs a groove by an etching process and therefore assumes substantially a semi-circular shape in section as shown in the sectional view of FIG. 2 (refer to “Manufacturing of Quartz-Made Electrophoretic Chip Using Micro-machining Technology and Evaluation of Its Basic Characteristics” by Hiroaki Nakanishi, et. al., Technical Review of Shimadzu Corporation (Shimadzu Hyouron), Vol. 1, Nos. 1-2, August 1998.)

Further, FIG. 3 is the perspective view showing an external configuration and an internal state of a micro-chemical chip 10 by way of an example where injection ports into the minute flow passage and electrodes 6 are provided.

Next, a method of utilizing this type of micro-chemical chip will be explained. One of the electrodes provided at both ends of the minute flow passage is set at a ground potential, and a predetermined voltage is applied to the other electrode, with the result that there occurs an electrophoretic phenomenon in which a sample (DNA, etc.) electrified to a minus side migrates to a plus electrode side. In this example, the sample flows together with a buffer solution to the plus electrode side from the ground side of the quantitative flow passage and is accumulated at an intersecting point by a quantity equivalent to a capacity of this portion. Subsequently, the sample flows along the detection flow passage toward the plus side. At this time, the DNAs have different charging quantities depending on their lengths and are different in terms of interaction with the meshed structure of the gel sealed therein. Therefore, the DNAs advance faster as they are shorter in their lengths. Accordingly, on-flow passage positions are different depending on the lengths of the DNAs, whereby the DNAs can be separated.

The thus separated DNAs can be observed by measuring a light quantity in a way that utilizes an absorption of ultraviolet rays or decorating the DNAs with phosphors.

FIG. 4 is a schematic view showing an integration of functions of the micro-chemical chip. FIG. 4 shows such a feasibility that two chemicals A, B are mixed and reacted or separated on the flow passage, and a substance on the flow passage is detected using a light transmission.

The quartz as the material of the transparent substrate is, however, a substance that is extremely hard to be etched and is therefore difficult to be worked. An etching rate of the quartz is as small as 1 μm or less for one minute, depending on conditions, and a mass-production thereof was difficult. Further, the formation of an insertion port for injecting the DNAs, etc. generally involves a method of providing a flat substrate member with an opening formed therein and a connector fitted thereto, and this type of structure is also a hindrance to the workability and the mass-productivity.

Moreover, there is a case where measurement assisting elements such as functional thin layers and chip-like silicon circuits are disposed in the vicinity of the minute flow passages in order to electronically measure products related to these minute flow passages. It has hitherto been, however, general that these measuring elements and incidental elements and components are disposed on the upper surfaces or lower surfaces of the flow passages, and it is difficult to say that the areas peripheral to the minute flow passages are utilized optimally and efficiently.

Further, as a method of utilizing the minute flow passage, there is a case where the measurement is simply conducted, and, in addition, a physical environment around the minute flow passage is adjusted. For example, there is a case in which a heater for raising an ambient temperature of the minute flow passage or a coolant tube for lowering the temperature are provided adjacent to the minute flow passage. These physical environment adjusting devices are disposed only upwardly and downwardly of the flow passage in the prior art.

Moreover, in the case of configuring the minute flow passage by press-molding (refer to Japanese Patent Application No. 2002-894956), a die assembly needs to have a protruded portion serving as a negative portion of the flow passage, and the formation of this protruded portion must involve cutting over a wide area mechanically or by etching. In the press-molding, a surface pattern of the die assembly is exactly transferred onto a material, and the working needs spending a considerable period of time in order to ensure the accuracy.

### SUMMARY OF THE INVENTION

It is an object of the present invention to provide a minute flow passage enabling a measurement assisting element and a physical environment adjusting device to be disposed in the periphery thereof, and a micro-chemical chip including the minute flow passage, which exhibit excellent workability and mass-productivity.

According to an embodiment of the present invention, there is provided a minute flow passage comprising first and second flat members disposed facing each other, wherein protruded flow passage walls provided on their surfaces opposite to each other configure the minute flow passage.

According to another embodiment of the present invention, there is provided a minute flow passage comprising a first flat member including a pair of wall members spaced a width of the minute flow passage from each other and provided in a protruded shape on one surface, and a second flat member fitted so as to abut on at least an apex portion of the wall member, wherein the minute flow passage is configured by a closed air space defined by the surface of the first flat member, the wall members and the second flat member.

According to still further embodiment, there is provided a minute flow passage comprising a first flat member including a first wall member structuring one side wall of the minute flow passage and formed in a protruded shape, and a second flat member including a second wall member structuring the other side wall of the minute flow passage and formed in a protruded shape, wherein the surface of the first flat member and the second flat member are disposed facing each other so that the width of the minute flow passage is defined by the first wall member and the second wall member.

### BRIEF DESCRIPTION OF THE DRAWINGS

FIG. 1 is an explanatory perspective view showing a configuration of a conventional micro-chemical chip;

FIG. 2 is an explanatory sectional view showing a groove utilized on the conventional micro-chemical chip;

FIG. 3 is a perspective view showing an external configuration of the micro-chemical chip as a complete product;

FIG. 4 is an explanatory view showing functions of the micro-chemical chip;

FIG. 5 is a sectional view showing how a minute flow passage is formed in an embodiment of the present invention;

FIG. 6 is a sectional view showing how the minute flow passage is formed in another embodiment of the present invention;

FIG. 7 is an explanatory view showing the minute flow passage formed in a curvilinear shape;

FIG. 8 is an explanatory view showing the minute flow passage formed in a bending shape;

FIG. 9 is a sectional view showing an embodiment where a flow passage is configured by providing a bonding layer on a side surface of a wall member;

FIG. 10 is a sectional view showing how a substrate including wall members configuring the minute flow passage is molded by a die assembly;

FIG. 11 is a sectional view showing an embodiment in which the wall member of the minute flow passage is utilized for an reflection optical system;

FIG. 12 is a sectional view showing an embodiment in which a flat substrate is provided with a light emitting device and a light receiving device;

FIG. 13 is a sectional view showing an embodiment in which the wall member is provided with the light emitting device and the light receiving device;

FIG. 14 is a sectional view showing an embodiment in which one of the flat members is formed as a silicon substrate;

FIG. 15 is an explanatory sectional view showing an embodiment in which a heating source is provided for controlling a temperature in the minute flow passage;

FIG. 16 is a sectional view showing an embodiment in which a heating/cooling tube is distributed in the vicinity of the minute flow passage; and

FIG. 17 is a sectional view showing an embodiment in which a porous member is provided.

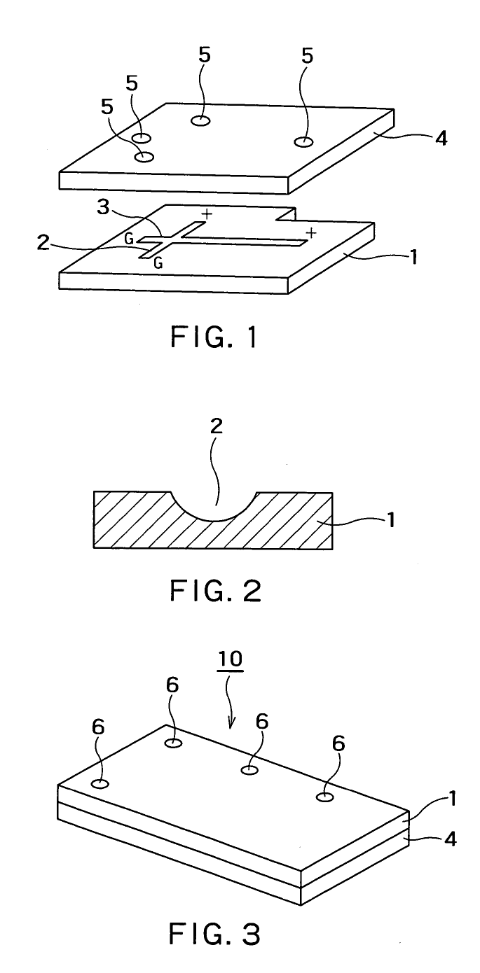

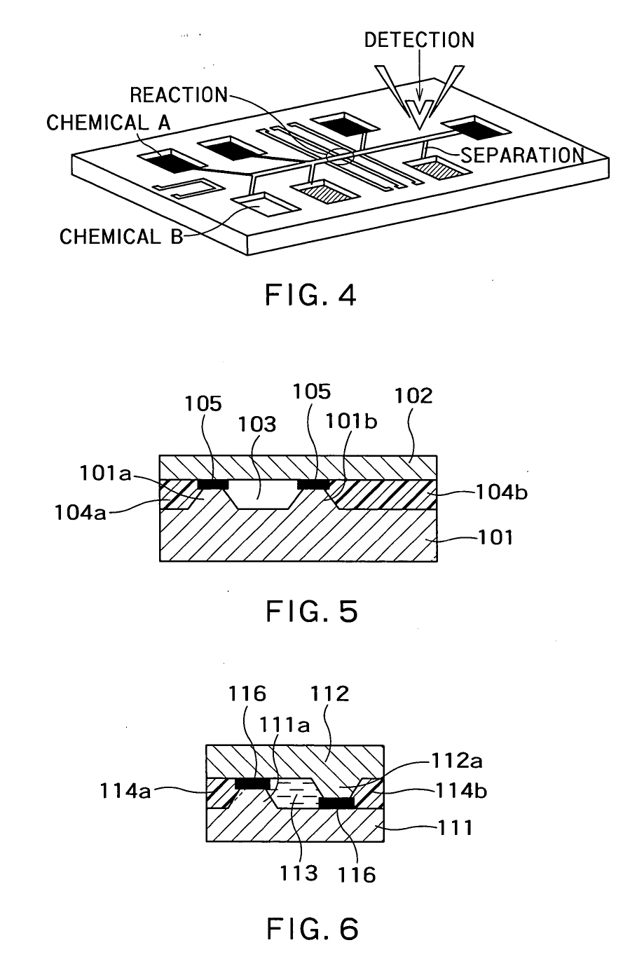

### DETAILED DESCRIPTION

A few embodiments of the present invention will hereinafter be described with reference to the accompanying drawings.

FIG. 5 is a sectional view showing a first embodiment of a minute flow passage (capillary) according to the present invention, which is utilized for a micro-chemical chip.

A flat substrate 101 is provided with protruded wall members 101a, 101b each taking substantially a trapezoidal or triangular shape in section and spaced a flow passage width from each other. A second flat substrate 102 is placed on these wall members, whereby a closed air space configures a flow passage 103. A bonding layer 105 is interposed between the second flat substrate 102 and the wall members 101a, 101b, thus bonding these members and the substrate together.

Air spaces 104a, 104b disposed more outside than the flow passage 103 configured by the wall members 101a, 101b, may remain hollowed if sufficient of a bonding strength. A component element for observing an interior of the flow passage and an environmental adjustment component can be installed in these air spaces 104a, 104b. Further, if not sufficient of the bonding strength, a filler such as a thermosetting resin, etc. can be injected and hardened.

Note that the flow passage be extended towards an inner side from this side as viewed substantially from on the sheet surface, and both side ends of the flow passage be provided with electrodes and injection port/take-out port (not shown). This minute flow passage is basically structured to be opened in a flowing direction and is therefore easy to further extend the flow passage by use of a joint means or a connective means matching with its material and to combine with flow passages having different functions.

FIG. 6 is a sectional view showing a second embodiment of the minute flow passage according to the present invention, wherein absolutely the same configuration as above is taken with respect to the direction of the flow passage and the positions of the electrodes and the injection port/take-out port (unillustrated).

According to the second embodiment, a first flat substrate 111 including a wall member 111a taking substantially a trapezoidal or triangular shape and a second flat substrate 112 including a wall member 112a taking substantially the trapezoidal or triangular shape, are set facing each other in a state of reversing these substrates 111, 112. A closed air space 111 formed by this structure is utilized as a minute flow passage. As in the first embodiment, a bonding layer 115 is interposed between the wall members and the flat substrates abutting on these wall members, thus bonding these members and the substrates together.

In the second embodiment also, air spaces 114a, 114b disposed more outside than the flow passage 103 configured by the wall members 111a, 112a, may remain hollowed or may also be hardened by injecting the filler such as the thermosetting resin, a glass, etc., depending on the bonding strength.

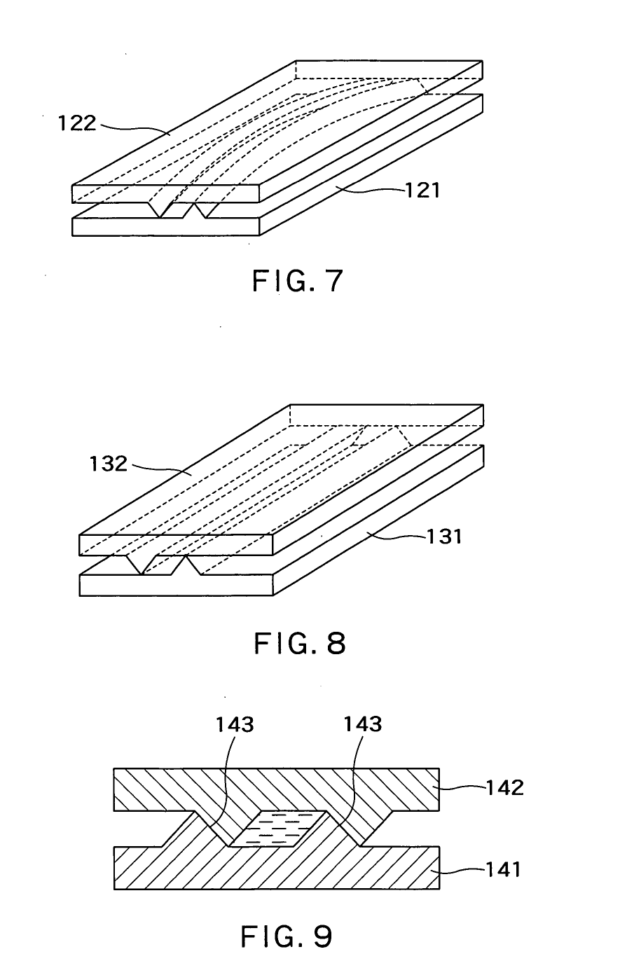

What is characteristic of the second embodiment is that the number of components can be reduced and a width of the minute flow passage can be adjusted as it is intended. Namely, a distance between the two wall members 111a, 111b can be adjusted as it is intended, and hence a minute flow passage width suited to an application can be selected. Note that the wall member is not limited to the linear shape and can take a variety of shapes as flat substrates 121, 122 have curvilinear wall members illustrated in FIG. 7 and flat substrates 131, 132 have zigzagged wall members illustrated in FIG. 8 have.

FIG. 9 illustrates a third embodiment, wherein flat substrates 141, 142, on which wall members each taking the triangular shape in section are disposed by twos in parallel, are inverted and thus combined with each other. In this case, angles of the wall members of the flat substrates facing each other are set such angles that the entire walls abut on each other, and an adhesive 143 is coated over this contact surface so as to fix the walls. According to the third embodiment, the angle of the wall member is set at 600 to the horizon. As a result, a bonding area can be taken large, and therefore a strength can be ensured even if the filler is not injected into the air space.

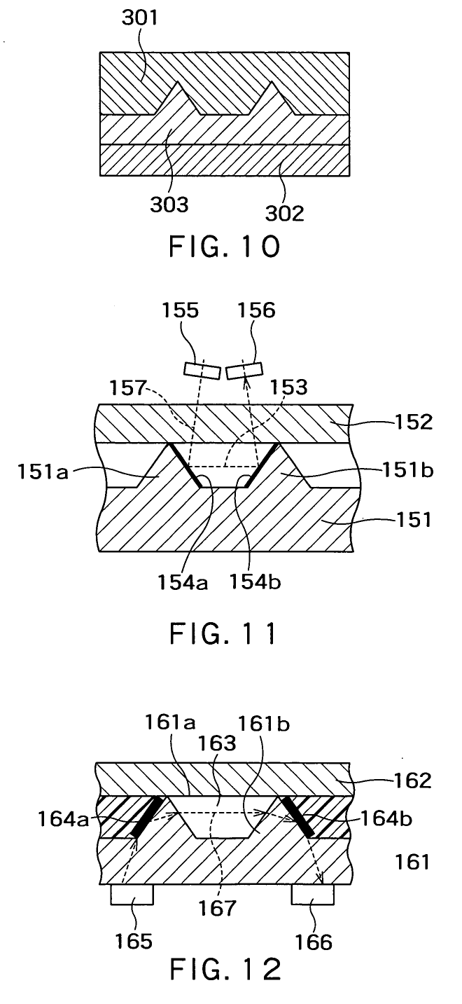

FIG. 10 is a schematic diagram showing a method of manufacturing by molding the flat substrate having the wall members described above. Herein, FIG. 10 illustrates how pressing is done with a quartz material 303 interposed between an upper die 301 and a lower die 302.

Thus, the quartz is utilized for the minute flow passage of the micro-chemical chip etc. in terms of a chemical resistance and an optical characteristic. Since a vacuum/high-temperature working environment is required of the quartz, it is difficult to apply a metallic die assembly, and glass-like carbon is often used as a preferable material. This material is, however, hard to work and is no better than being worked to dig a groove in the present situation. According to the invention of the present application, each of the flat substrates including the protruded wall members are obtained by use of this groove-worked die assembly. Accordingly, the die assembly does not need cutting and etching on its flat surface having a large area, and hence a mass-production can be attained, resulting in a decrease in manufacturing costs. For example, in a case where the quarts is formed with a groove that is approximately 100 μm deep, this process has required so far several hours as a working time. According to the configuration of the present invention, however, the formation of the minute flow passage is finished within several minutes.

Incidentally, if some contrivance is given to the shape of the wall member, a cross flow passage can be formed in both of the first and second embodiments. Further, the injection well and the take-out well can be easily formed by additionally working the flat substrate.

An embodiment for giving a variety of functions to air spaces in the vicinity of the minute flow passage, will be discussed.

The minute flow passage in each of the embodiments discussed above has such a structure that the areas (directions) other than the flowing direction are surrounded by the walls, and hence the variety of members, components, elements, etc. can be disposed therein. There can be disposed, e.g., a sensor for observing an internal condition of the flow passage, an elemental component for changing a physical environment such as the heat, the electromagnetism, etc. Further, in case of executing an optical treatment, a part of the wall member is utilized by its being molded in a shape of an optical component. Moreover, in the case of using the sensor, etc. built up on a silicon member, this member itself is utilized for a wall surface configuring the flow passage.

The connection of the flow passage and an injection of a test sample involve installing members related to the sectional direction of the flow in terms of the structure of the minute flow passage according to the present invention.

Typical examples will hereinafter be explained in detail.

FIG. 11 is a sectional view showing an embodiment wherein the wall member of the minute flow passage is utilized for a reflection optical system.

In this embodiment, reflection layers 154a, 154b are formed on the surfaces of wall members 151a, 151b configuring a minute flow passage 153 of a flat substrate 151. Then, a light emitting element 155 such as an LED, etc. and a light receiving element 156 such as PD, etc. are disposed on an upper substrate 152 in consideration of a refractive index of the flat member, and a light path 157 traversing round the minute flow passage is built up.

This structure enables a speed measurement and a spectral measurement of a fluid in the minute flow passage.

FIG. 12 is a sectional view illustrating an embodiment wherein the wall member of the minute flow passage is utilized for the reflection optical system as in FIG. 11. This embodiment has a difference that a light emitting element 165 and a light receiving element 166 are disposed under a flat substrate 161. Namely, a characteristic point is that a light path is built up by utilizing an internal reflection and refraction of each of wall members 161a, 161b.

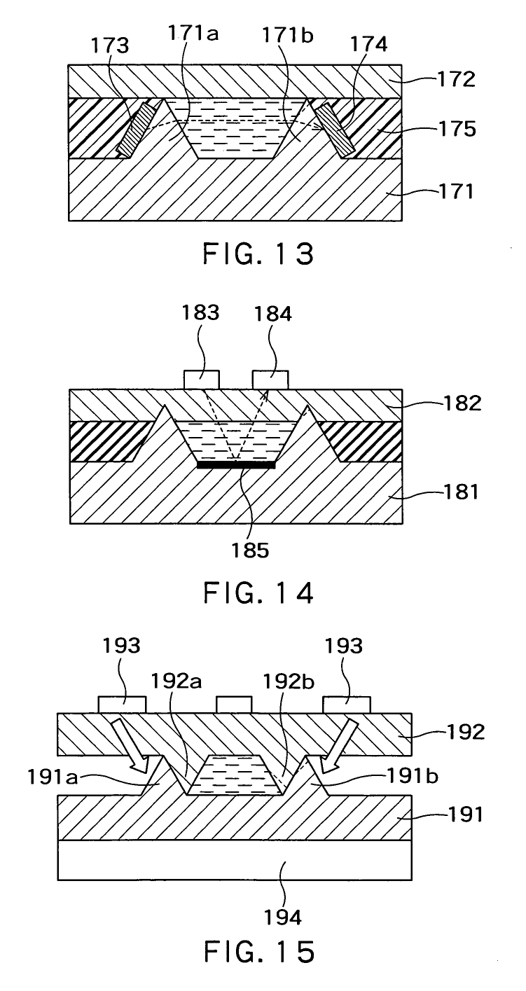

FIG. 13 illustrates an embodiment wherein an area outside the wall member is effectively employed. A light emitting element 173 and a light receiving element 174 are disposed directly on the surfaces of wall members 171a, 171b. For disposing the light emitting element 173 and the light receiving element 174, a layer forming process may be effected directly on the surfaces of the wall members, and the light emitting element 173 and the light receiving element 174 may also be assembled in air spaces between the upper and lower flat substrates later on. Material 175 filling these air spaces later on serves as molding materials for the light emitting element 173 and the light receiving element 174.

FIG. 14 is a sectional view showing an embodiment wherein one of the flat members is formed as a silicon substrate. Namely, a first flat substrate 181 has the same structure as in the case of each of the embodiments discussed so far, however, a second flat substrate 182 superposed thereon is the silicon substrate. A variety of sensor devices and electronic circuits for processing can be provided directly on this silicon substrate 182. In an example shown in FIG. 14, a light emitting element 183 and a light receiving element 184 are provided on the silicon substrate 182.

Further, according to this embodiment, a reflection layer 185 is provided on the bottom surface of the flow passage, and there is formed a light path along which the light emitted from the light emitting element 183 travels via the flow passage, and, after being reflected by the reflection layer 185 provided on the bottom surface, reaches the light receiving element 184. Further, an apex angle θ of the wall member is set narrower than an angle that is peculiarly specified when etching a silicon crystal, thereby attaining the facility for positioning.

Note that materials other than silicon can be used for the flat substrates, however, in this case working of a groove for positioning and the apex angle θ may be set corresponding to the material.

What has been discussed so far is an exemplification of the optical device, however, even in the case of a temperature device and an electromagnetic device, the layers matching with the characteristics can be provided in areas in the vicinity of the flow passage. The followings are discussions on such embodiments.

FIG. 15 is an explanatory sectional view showing an embodiment wherein temperature control within the minute flow passage can be performed.

This embodiment gives a dimensional relationship in which outer walls of wall members 192a, 192b provided on a second flat substrate 192 are fitted to inner walls of wall members 191a, 191b provided on a first flat substrate 191, and a flow passage is formed by combining those walls.

On the other hand, a cooling source 194 is provided on a lower surface of the first flat substrate 191, and a heating source 193 is provided on an upper surface of the second flat substrate 192. These heating and cooling sources are disposed along the flow passage as the necessity may arise. The heating source can involve the use of a normal heater and a hot air, while the cooling source can involve using a variety of heating sources such as a water cooling pipe and so on. If utilizing a laser constructed in proper dimensions and infrared rays formed in proper dimensions as well, however, the temperature can be raised in an area corresponding to the dimensions of this heat source only when heating. An arrowhead in FIG. 15 indicates a heat transfer from the heating source. Further, a Peltier element, a heat sink and a fan are used as the cooling source, whereby similarly the temperature can be lowered by the cooling source when the heating is stopped.

Moreover, a temperature measuring element 195 is fitted onto the second flat substrate just above the flow passage, whereby the temperature can be controlled by use of an unillustrated control device.

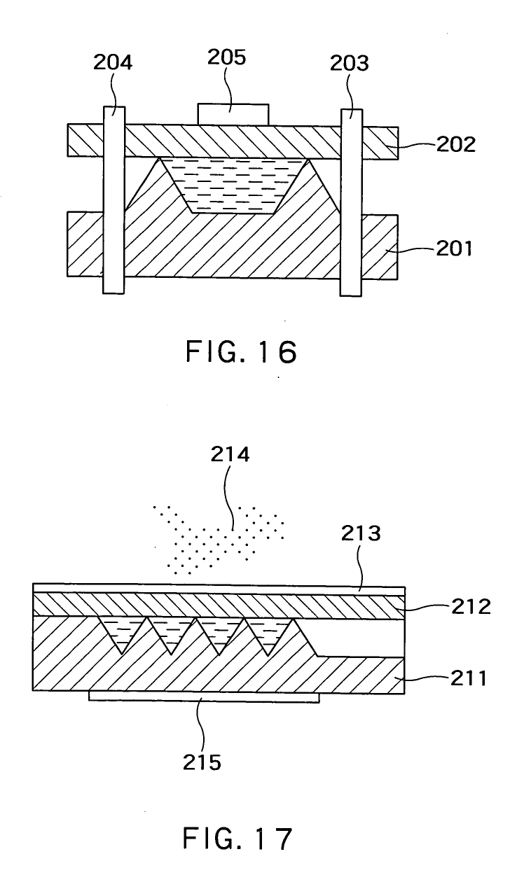

FIG. 16 illustrates an embodiment contrived for heating and cooling, wherein the same configuration as the embodiments discussed so far have is that there are provided the first flat substrate 201 and the second flat substrate placed thereon, however, a different point is that a heating tube 203 and a cooling tube 204 are so provided in the vicinity of the minute flow passage as to penetrate these substrates.

Moreover, a temperature control element is provided on the second flat substrate just above the flow passage. Based on a result of the measurement thereof, a heat carrier is supplied to those tubes, or alternatively a coolant is supplied thereto, thereby enabling a temperature in the flow passage area to be controlled.

Configurations of the heat source, the cooling source, the temperature measuring element and the minute flow passage can be arbitrarily combined in accordance with purposes. Further, a temperature control range can be also arbitrarily selected. Note that the same distributing method can be applied also to a case of utilizing the electromagnetism and an optical ray source in addition to the temperature in the configuration as shown in FIG. 16.

FIG. 17 is a sectional view illustrating a still further embodiment. According to the respective embodiments discussed above, the flat substrate is the glass plate, etc. composed of a dense material. In this embodiment, however, a porous substrate 212 is fitted onto the first flat substrate 211 formed with grooves so that the flow passages each taking substantially a triangular shape in section are disposed side by side. Then, a functional substance layer 213 is provided on this porous substrate 212. This functional substance layer has a selective property. Moreover, a heat source 215 is provided on the lower surface of the first flat substrate 212.

In this type of flow passage, if a substance smaller than a hole size of the porous member exists within the flow passage, this substance selectively permeates and flows outside as indicated by a reference numeral 214. As a result, a pressure difference occurs inwardly and outwardly of the flow passage and is enhanced by pressurizing the transmitted substance in the flow passage with a pressure source or giving a thermal energy to the in-flow passage substance by heating it with a heat source 215. Further, laser irradiation and a reactive energy of the substance can be also utilized.

A layer, etc. exhibiting a function of enhancing the selectivity of the substance is used as the functional substance added to the surface of the porous substrate or to the interior of the hole. In this respect, generally the permeation of the substance through the porous substrate is preferable at a higher temperature. In order to make thermal expansion coefficients of the substrates on the flow passage side and on the sealing side approximate to each other, however, if, e.g., quartz is used for the substrate on the flow passage side, a high silicate component glass is sued for the substrate on the sealing side, and a substance obtained by sintering Rh and silica sol is used, thereby enabling hydrogen being selective.

In each of the embodiments discussed so far, the substrate is substantially flat, while the wall member is rectangular such as being triangular or trapezoidal in section. The shape is not, if possible of working, limited to those exemplified above. For instance, the substrate may be corrugated, and the minute flow passages to be configured are not required to have the same depth and height.

As explained above, according to the embodiments of the present invention, the minute flow passage is configured by assembling the press-molded components and is therefore easy of the die working and excellent of the mass-productivity.

Further, the minute flow passage has a multiplicity of air gaps outwardly of the wall members configuring the flow passage, wherein the variety of functional components, etc. can be disposed in those air gaps, and the utility can be enhanced.

Moreover, the minute flow passage is formed by disposing the two flat substrates each having the protruded portions serving as the wall members in the face-to-face relationship, whereby the flow passage width can be adjusted, though hitherto impossible.

What is claimed is:

1. A minute flow passage comprising:
first and second flat members disposed facing each other,
wherein protruded flow passage walls provided on their surfaces opposite to each other configure said minute flow passage.

2. The minute flow passage according to claim 1, wherein said flow passage walls are all provided on any one of said first and second flat members, and said other flat member is a flat plate.

3. The minute flow passage according to claim 1, wherein one side walls and the other side walls of said flow passage walls configuring said minute flow passage are provided on said first and second flat members.

4. The minute flow passage according to claim 1, wherein said flat member is composed of a glass.

5. The minute flow passage according to claim 1, wherein areas between said first and second flat members other than areas surrounded by said flow passage walls are filled with a filling material.

6. The minute flow passage according to claim 1, wherein said flow passage wall takes substantially a trapezoidal shape in section, and
at least one of side surfaces of said flow passage wall is provided with a light reflection layer.

7. A minute flow passage comprising:
a first flat member including a pair of wall members spaced a width of said minute flow passage from each other and provided in a protruded shape on one surface; and
a second flat member fitted so as to abut on at least an apex portion of said wall member,
wherein said minute flow passage is configured by a closed air space defined by the surface of said first flat member, said wall members and said second flat member.

8. The minute flow passage according to claim 7, wherein said flat member is composed of a glass.

9. The minute flow passage according to claim 7, wherein areas between said first and second flat members other than areas surrounded by said flow passage walls are filled with a filler.

10. The minute flow passage according to claim 7, wherein said flow passage wall takes a triangular or substantially a trapezoidal shape in section, and
at least one of side surfaces of said flow passage wall is provided with a light reflection layer.

11. The minute flow passage according to claim 7, wherein the surface of said flow passage wall is provided with an optical element.

12. The minute flow passage according to claim 7, wherein said second flat member is a semiconductor substrate.

13. The minute flow passage according to claim 7, wherein an active element is provided on said semiconductor substrate.

14. The minute flow passage according to claim 7, wherein an element for raising and lowering a temperature is provided in the vicinity of said minute flow passage.

15. The minute flow passage according to claim 7, wherein said second flat member is composed of a porous material.

16. The minute flow passage according to claim 15, wherein a temperature raising element for raising the temperature is provided on the undersurface of said firs flat member.

17. A minute flow passage comprising:
a first flat member including a first wall member structuring one side wall of said minute flow passage and formed in a protruded shape; and
a second flat member including a second wall member structuring the other side wall of said minute flow passage and formed in a protruded shape,
wherein the surface of said first flat member and said second flat member are disposed facing each other so that the width of said minute flow passage is defined by said first wall member and said second wall member.

18. The minute flow passage according to claim 17, wherein said flat member is composed of a glass.

19. The minute flow passage according to claim 17, wherein areas between said first and second flat members other than areas surrounded by said flow passage walls are filled with a filler.

20. The minute flow passage according to claim 17, wherein said flow passage wall takes a triangular or substantially a trapezoidal shape in section, and
at least one of side surfaces thereof is provided with a light reflection layer.

21. The micro-chemical chip comprising:
a first flat member including a pair of wall members spaced a width of said minute flow passage from each other and provided in a protruded shape on one surface;
a second flat member fitted so as to abut on at least an apex portion of said wall member;
a plurality of minute flow passages, each configured by a closed air space defined by the surface of said first flat member, the wall members and said second flat member, for performing reaction with or separation of a chemical substance;
wells provided at end portions of said plurality of minute flow passages; and
an optical element, provided midways of said minute flow passage, for analyzing.

22. The micro-chemical chip according to claim 21, wherein said optical element is an optical lens fitted to said first or second flat member.

23. A micro-chemical chip comprising:
minute flow passages each configured by protruded flow passage walls provided on the surfaces, opposite each other, of first and second flat members disposed facing each other;
wells provided end portions of said plurality of minute flow passages; and
an optical element, provided midways of said minute flow passage, for analyzing.

24. The micro-chemical chip according to claim 23, wherein said flow passage wall takes substantially a triangular or trapezoidal shape in section, and
at least one of side surfaces thereof is provided with a light reflection layer.
